(19) United States
(12) Patent Application Publication
(10) Pub. No.: US 2025/0327181 A1
(43) Pub. Date: Oct. 23, 2025

(54) GAS SPRAYING APPARATUS, SUBSTRATE PROCESSING APPARATUS, AND THIN FILM DEPOSITION METHOD

(71) Applicant: JUSUNG ENGINEERING CO., LTD., Gwangju-si, Gyeonggi-do (KR)

(72) Inventors: Won Tae CHO, Gwangju-Si, Gyeonggi-Do (KR); Chul Joo HWANG, Gwangju-Si, Gyeonggi-Do (KR)

(21) Appl. No.: 18/992,949

(22) PCT Filed: Jun. 30, 2023
(86) PCT No.: PCT/KR2023/009218

§ 371 Date: Jan. 9, 2025

(30) Foreign Application Priority Data
Jul. 8, 2022 (KR) 10-2022-0084161
Jun. 23, 2023 (KR) 10-2023-0081365

(51) Int. Cl. C23C 16/455; C23C 16/509

(52) U.S. Cl. CPC C23C 16/45561; C23C 16/509

(57) ABSTRACT

Provided are a gas injection device, an apparatus for processing a substrate, and a method for depositing a thin film, and more particularly, a gas injection device that injects a gas onto a substrate to deposit a thin film, an apparatus for processing a substrate, and a method for depositing a thin film. A gas injection device in accordance with an exemplary embodiment include a first plate in which a first gas supply path and a second gas supply path are provided to be separated from each other and which has a first gas supply hole and a second gas supply hole, which are connected to the first gas supply path and the second gas supply path, respectively, and a second plate spaced apart from the first plate and having a plurality of openings arranged alternately with the first gas supply hole and the second gas supply hole.

### BACKGROUND

The present disclosure relates to a gas injection device, an apparatus for processing a substrate, and a method for depositing a thin film, and more particularly, to a gas injection device that injects a gas onto a substrate to deposit a thin film, an apparatus for processing a substrate, and a method for depositing a thin film.

In general, a semiconductor device or display device is manufactured by depositing various material on a substrate in a thin film shape and patterning the deposited thin film. For this, several stages of different processes such as a deposition process, an etching process, a cleaning process, and a drying process are performed.

Here, the deposition process is performed to form a thin film having properties required as a semiconductor device or display device on the substrate. Such a deposition process is generally performed by an apparatus for processing a substrate, in which a process gas is injected using a gas injection device, in which a plurality of injection holes are formed, to form a thin film on the substrate through chemical reaction.

As described above, in forming the thin film on the substrate using the gas injection device, in which the plurality of injection holes are formed, securing of deposition uniformity is a very important issue. Thus, demands for the gas injection device having an improved opening structure to uniformly deposit the thin film are continuously increasing.

### SUMMARY

The present disclosure provides a gas injection device capable of depositing a uniform thin film, an apparatus for processing a substrate, and a method for depositing a thin film.

In accordance with an exemplary embodiment, a gas injection device includes: a first plate in which a first gas supply path and a second gas supply path are provided to be separated from each other and which has a first gas supply hole and a second gas supply hole, which are connected to the first gas supply path and the second gas supply path, respectively; and a second plate spaced apart from the first plate and having a plurality of openings arranged alternately with the first gas supply hole and the second gas supply hole.

The second plate may be disposed to be spaced an interval of 1 mm to 3 mm from the first plate.

The openings may include: a first opening defined in a side of the first plate; and a second opening connected to the first opening and having a diameter greater than that of the first opening.

The first opening may have a diameter of 1 mm to 3 mm.

The second opening may have a diameter of 10 mm to 14 mm.

The openings may further include a third opening configured to connect the first opening to the second opening between the first opening and the second opening.

The third opening may have a shape of which a cross-section gradually increases toward the second opening.

The second opening may have a length of 25 mm to 75 mm.

The second plate may have a thickness of 35 mm to 100 mm.

The openings may be arranged at an interval of 12 mm to 20 mm.

The first opening and the second opening may have lengths different from each other.

The first opening may have a length greater than that of the second opening.

The second opening may have a length greater than that of the first opening.

In accordance with another exemplary embodiment, an apparatus for processing a substrate includes: a chamber; a substrate support device installed in the chamber to support the substrate; a gas injection device mentioned above, which is installed in the chamber to inject a gas to the substrate support device; and a power supply device connected to the gas injection device to supply power to the gas injection device.

The first plate and the second plate may be electrically insulated from each other, and the power supply device may be connected to the second plate to supply power to the second plate.

The power supply device may be configured to supply power to the first plate and the second plate.

In accordance with yet another exemplary embodiment, a method for depositing a thin film by using the above-described gas injection device, wherein a first gas is supplied through the first gas supply path, and a second gas is supplied through the second gas supply path to deposit the thin film on the substrate.

At least one of the first gas or the second gas may be supplied to deposit the thin film on the substrate in a chemical vapor deposition (CVD) manner or an atomic layer deposition (ALD) manner.

The thin film may include at least one of an IZO thin film in which indium (In) is doped into zinc oxide (ZnO), a GZO thin film in which gallium (Ga) is doped into zinc oxide (ZnO), an IGZO thin film in which indium (In) and gallium (Ga) are doped into zinc oxide (ZnO), a thin film having a high dielectric constant (High-K), a silicon oxide (SiO₂) thin film, or a silicon nitride (SiN) thin film.

According to the exemplary embodiment, the interval between the openings through which the process gas is injected may be minimized to improve the deposition uniformity.

In addition, the high-density plasma may be generated using the hollow cathode effect, and thus, the high-quality thin film may be formed.

### BRIEF DESCRIPTION OF THE DRAWINGS

FIG. 1 is a schematic view of an apparatus for processing a substrate in accordance with an exemplary embodiment;

FIG. 2 is a view illustrating an arrangement structure of openings in a gas injection device in accordance with an exemplary embodiment; and

FIG. 3 is a view illustrating a process of forming a supply hole and an opening in the gas injection device in accordance with an exemplary embodiment.

### DETAILED DESCRIPTION OF DISCLOSURE

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art.

It will also be understood that when a layer, a film, a region, or a substrate is referred to as being ‘on’ another one, it can be directly on the other one, or one or more intervening layers, films, regions, or substrates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the figures, the dimensions of layers and areas may be exaggerated for clarity of illustration. Like reference numerals refer to like elements throughout.

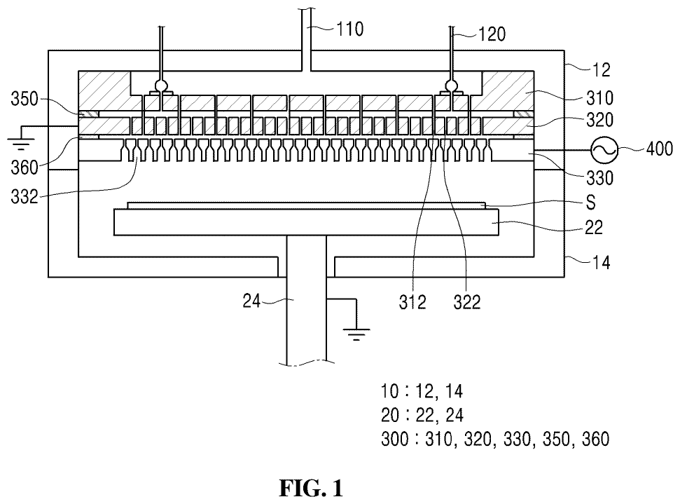

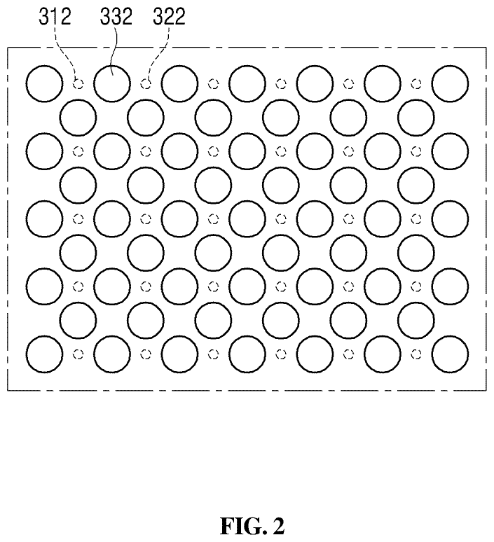

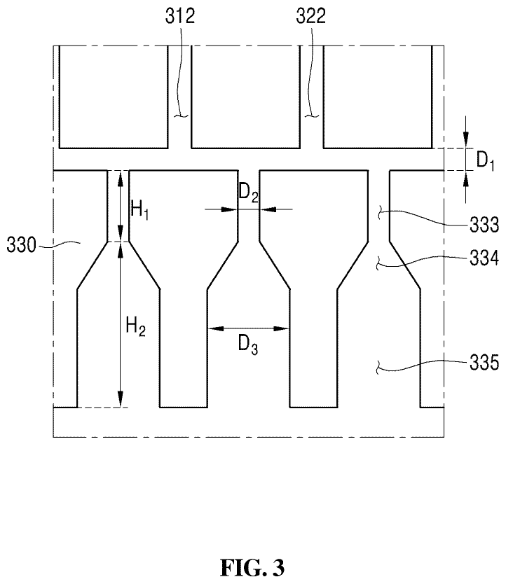

FIG. 1 is a schematic view of an apparatus for processing a substrate in accordance with an exemplary embodiment. FIG. 2 is a view illustrating an arrangement structure of openings in a gas injection device in accordance with an exemplary embodiment, and FIG. 3 is a view illustrating a process of forming a supply hole and an opening in the gas injection device in accordance with an exemplary embodiment.

Referring to FIGS. 1 to 3, an apparatus for processing a substrate in accordance with an exemplary embodiment includes a chamber 10, a substrate support device 20 provided in the chamber 10 and installed in the chamber 10 to support a substrate S provided in the chamber 10, a gas injection device 300 installed in the chamber 10 to inject a gas to the substrate support device 20, and a power supply device 400 connected to the gas injection device 300 to supply power for generating plasma in the chamber to the gas injection device 300. In addition, the apparatus for processing the substrate may further include a control device (not shown) for controlling the power supply device 400.

The chamber 10 provides a predetermined reaction space and is maintained to seal the reaction space. The chamber 10 may include a body 14 including an approximately circular or square-shaped planar part and a sidewall extending upward from the planar part and having a predetermined reaction space, and a lid 12 having an approximately circular or square shape and disposed on the body 14 to seal the reaction space. However, the chamber 10 is not limited thereto and may be manufactured in various shapes corresponding to a shape of the substrate S.

An exhaust port (not shown) may be provided on a predetermined area of a bottom surface of the chamber 10, and an exhaust tube (not shown) connected to the exhaust port may be provided outside the chamber 10. Also, the exhaust tube may be connected to an exhaust device (not shown).

A vacuum pump such as a turbo molecular pump may be used as the exhaust device. Therefore, the inside of the chamber may be vacuumized under a predetermined reduced pressure atmosphere, for example, to a predetermined pressure of 0.1 mTorr or less by the exhaust device. The exhaust tube may be installed not only on the bottom surface of the chamber 10, but also on a side surface of the chamber 10 below the substrate support device 20 to be described later. In addition, a plurality of exhaust tubes and the exhaust device corresponding thereto may be further installed to reduce an exhaust time.

The substrate S provided into the chamber 10 may be seated on the substrate support device 20 to perform a substrate processing process, for example, a thin film deposition process. As described above, the substrate support device 20 may include an electrostatic chuck to adsorb and maintain the substrate S by using electrostatic force so that the substrate S is seated and supported. Alternatively, the substrate support device 20 may support the substrate S through vacuum adsorption or mechanical force.

The substrate support device 20 may be provided in a shape corresponding to a shape of the substrate S, for example, a circular shape or a rectangular shape. The substrate support device 20 may include a substrate support 22 on which the substrate S is seated and an elevator 24 disposed below the substrate support 22 to elevate the substrate support 22. Here, the substrate support 22 may be manufactured to be larger than the substrate S, and the elevator 24 may be provided to support at least one area of the substrate support 22, for example, a central portion. When the substrate S is seated on the substrate support 22, the substrate support 22 may move to approach the gas injection device 300. Also, a heater (not shown) may be installed in the substrate support 22. The heater generates heat to a predetermined temperature to heat the substrate support 22 and the substrate S seated on the substrate support 22 so that the thin film is uniformly deposited on the substrate S.

A gas supply device may be installed in the lid 12 of the chamber 10. The gas supply device may be installed to pass through the lid 12 of the chamber 10 and may include a first gas supply part 50 and a second gas supply part 60 to provide a first gas and a second gas to the gas injection device 300, respectively. Here, the first gas may include a source gas, and the second gas may include a reaction gas. However, it is not limited thereto, and the first gas may include a reaction gas, and the second gas may include a source gas, or at least one of the first gas or the second gas may include a mixed gas in which the source gas and the reaction gas are mixed. In addition, at least one of the first gas and the second gas may be a purge gas. That is, each of the first gas supply part and the second gas supply part may not necessarily provide one gas. For example, each of the first gas supply part and the second gas supply part may be configured to supply a plurality of gases at the same time or supply a gas selected from the plurality of gases.

The gas injection device 300 is installed inside the chamber 10, for example, on a bottom surface of the lid 12, and a first gas supply path for injection and supplying the first gas onto the substrate and a second gas supply path for injecting and supplying the second gas onto the substrate may be provided in the gas injection device 300. The first gas supply path and the second gas supply path may be provided to be independently separated from each other so that the first gas and the second gas are separated from each other without being mixed with each other within the gas injection device 300 and then are supplied onto the substrate.

In more detail, the gas injection device 300 includes a first plate in which the first gas supply path and the second gas supply path are provided to be separated from each other and which has a first gas supply hole 312 and a second gas supply hole 314, which are connected to the first gas supply path and the second gas supply path, respectively, and a second plate 330 spaced apart from the first plate and having a plurality of openings 332 arranged alternately with the first gas supply hole 312 and the second gas supply hole 314.

The first plate may include an upper frame 310 and a lower frame 320. Here, the upper frame 310 is detachably coupled to the bottom surface of the lid 12, and simultaneously, a portion of a top surface of the upper frame 310, for example, a central portion of the top surface of the upper frame 310 is spaced a predetermined distance from the bottom surface of the lid 12. Thus, the first gas supplied from the first gas supply part may be diffused into a space between the top surface of the upper frame 310 and the bottom surface of the lid 12. In addition, the lower frame 320 is installed to be spaced a predetermined distance from the bottom surface of the upper frame 310. Thus, the second gas supplied from the second gas supply part 60 may be diffused into a space between the top surface of the lower frame 320 and the bottom surface of the upper frame 310. The upper frame 310 and the lower frame 320 may be connected to each other along an outer circumferential surface to provide the spaced space therein, and be integrated with each other, and may have a structure that seals the outer circumferential surface by a first sealing member 350. Here, the first sealing member 350 may be made of an insulating material to electrically insulate the upper frame 310 from the lower frame 320, or conversely, the first sealing member 350 may be made of a conductive material to electrically connect the upper frame 310 to the lower frame 320.

In the first gas supply path, the first gas supplied from the first gas supply part 110 may be diffused into the space between the bottom surface of the lid 12 and the upper frame 310 to pass through the upper frame 310 and the lower frame 320 and then be supplied into the chamber 10. Here, the first gas supply hole 312 may be connected to the first gas supply path and may be defined to pass through the upper frame 310 and the lower frame 320 so as to be isolated from the space between the top surface of the lower frame 320 and the bottom surface of the upper frame 310 at a lower portion of the space between the top surface of the upper frame 310 and the bottom surface of the lid 12.

In addition, in the second gas supply path, the second gas supplied from the second gas supply part 120 may be diffused in the space between the bottom surface of the upper frame 310 and the top surface of the lower frame 320 to pass through the lower frame 320 and then be supplied into the chamber 10. Here, the second gas supply hole 322 may be defined to be connected to the second gas supply path and may be defined to pass through the lower frame 320 at a lower portion of the space between the upper frame 310 and the bottom surface.

Thus, the first gas supply path and the second gas supply path may not communicate with each other, and the first gas and the second gas may be separately supplied from the gas supply device to the lower side via the first plate.

The second plate 330 may be installed to be spaced apart from a lower side of the lower frame 320. That is, the second plate 330 is installed at a predetermined distance D₁ from the bottom surface of the lower frame 320. Thus, the first gas and the second gas supplied downward via the first plate may be diffused in a space between the top surface of the second plate 330 and the bottom surface of the lower frame 320. The lower frame 320 and the second plate 330 may be connected along an outer circumferential surface and be integrated with each other to provide a separation space therein, but may be configured to seal the outer circumferential surface by a second sealing member 360. Here, the second sealing member 360 may be made of an insulating material to electrically insulate the lower frame 320 therefrom or, conversely, may be made of a conductive material to electrically connect the lower frame 320 to the second plate 330.

Here, the second plate 330 may be installed to be spaced downward from the first plate by a distance at which a plasma sheath area defined on a surface of the first plate, i.e., the bottom surface of the lower frame 320, and a plasma sheath area defined on a surface of the second plate 330, i.e., the top surface of the second plate 330, overlap each other. Here, the plasma sheath area refers to a dark field area on which positive (+) ions are concentrated between the plasma and a surface of the structure so that energy is exchanged, but plasma is hardly generated.

If the plasma sheath area defined on the bottom surface of the lower frame 320 and the plasma sheath area defined on the top surface of the second plate 330 do not overlap each other, plasma may be generated between the plasma sheath areas. However, in this embodiment, since the lower frame 320 and the second plate 330 are disposed to be spaced apart from each other by the distance at which the plasma sheath area defined on the bottom surface of the lower frame 320 and the plasma sheath area defined on the top surface of the second plate 330 overlap each other, plasma may be prevented from being generated between the bottom surface of the lower frame 320 and the top surface of the second plate 330.

As described above, since the first gas and the second gas, which are supplied downward via the first plate are necessarily diffused into the space between the bottom surface of the lower frame 320 and the top surface of the second plate 330, the bottom surface of the lower frame 320 and the top surface of the second plate 330 have to be spaced apart from each other so that the gas smoothly flows. Thus, the second plate 330 may be spaced apart from the first plate by an interval of 1 mm to 3 mm. When the second plate 330 is disposed to be spaced a distance of less than 1 mm from the first plate, the gas may smoothly flow between the bottom surface of the lower frame 320 and the top surface of the second plate 330, and when the second plate 330 is disposed to be spaced a distance exceeding 3 mm from the first plate, plasma may be generated in the space between the bottom surface of the lower frame 320 and the top surface of the second plate 330 to generate particles, thereby causing process defects.

In addition, the second plate 330 has a plurality of openings 332 arranged alternately with the first gas supply hole 312 and the second gas supply hole 322, which are described above. That is, as illustrated in FIG. 2, when the first plate and the second plate 330 are viewed from the top or bottom, the plurality of openings 332 may be defined in the second plate 330 so as not to overlap any one of the first gas supply hole 312 and the second gas supply hole 322. When the first plate and the second plate 330 are viewed from the top or bottom, the plurality of openings 332 may be defined between the first gas supply hole 312 and the second gas supply hole 322 in at least one direction. In addition, the plurality of openings 332 may be defined to be disposed at central positions between the first gas supply hole 312 and the second gas supply hole 322 in the at least one direction.

If the openings 332 are disposed to overlap the first gas supply hole 312 and the second gas supply hole 314, most of the gas supplied from the first gas supply hole 312 and the second gas supply hole 314 may be injected by passing through the openings defined to overlap the first gas supply hole 312 and the second gas supply hole 314. However, the gas injected downward by passing through the openings 332 may not be all, and a portion of the gas may not be directly injected to the openings 332, but may flow into the space between the bottom surface of the lower frame 320 and the top surface of the second plate 330 and then be stagnant in the space. Since the stagnant gas obstructs the smooth flow of the gas to generate the particles, in this embodiment, the plurality of openings 332 may be defined in the second plate 330 so as to be arranged alternately with the first gas supply hole 312 and the second gas supply hole 322.

As illustrated in FIG. 3, the openings 332 may include a first opening 333 defined at a side of the first plate and a second opening 335 connected to the first opening 333 and having a diameter greater than that of the first opening 333. That is, each opening 332 may include a first opening 333 defined to a predetermined length H₁ from the top surface of the second plate 330 and a second opening defined to a predetermined length H₂ from the bottom surface of the second plate 330. Here, the first opening 333 is a gas inlet, and the gas diffused in the space between the bottom surface of the lower frame 320 and the top surface of the second plate 330 may be introduced into the opening 332 through the first opening 333. On the other hand, the second opening 335 is a gas outlet, and the gas introduced into the opening 332 is injected to a lower side of the second plate 330 through the second opening 335. The first opening 333 may be disposed alternately with the first gas supply hole 312 and the second gas supply hole 322, and the second opening 335 may extend to a lower side of the first opening 333 to have a diameter greater than the first opening 333. Each opening 332 may further include a third opening 334 connecting the first opening 333 to the second opening 335 between the first opening 333 and the second opening 335.

The first opening 333 induces the gas diffused between the bottom surface of the lower frame 320 and the top surface of the second plate 330 to the lower second opening 335. As described above, the first opening 333 has a diameter D₂ selected to uniformly induce the gas diffused between the bottom surface of the lower frame 320 and the top surface of the second plate 330 to each second opening 335. Here, the first opening 333 may have the diameter D₂ in which the plasma sheath region is defined. That is, in the first opening 333, the plasma sheath region that may be defined on an inner surface of the second plate 330 defining the first opening 333 overlaps entirely so that the plasma sheath in which the plasma is hardly generated therein is defined. For this, the first opening 333 may have a diameter D₂ of 1 mm to 3 mm. When the diameter D₂ of the first opening 333 is less than 1 mm, the gas may not smoothly flow through the first opening 333, and when the diameter D₂ exceeds 3 mm, the plasma may be generated in the first opening 333 to cause clogging due to the particles. As described above, the first opening 333 may be defined to have a length H₁ of 10 mm to 25 mm from the top surface of the second plate 330.

The third opening 334 serves to smoothly transfer the gas supplied through the first opening 333 from the lower side of the first opening 333 to the second opening 335. The third opening 334 may have a shape in which a cross-section increases from a lower end of the first opening 333 to an upper end of the second opening 335, and thus, the gas supplied through the first opening 333 may be induced through the third opening 334 without stagnation and then be smoothly transferred to the second opening 335. However, the third opening 334 may not be essential, and if the third opening 334 is omitted, the second opening 335 may be directly connected to a lower side of the first opening 333.

The second opening 335 is connected to the lower side of the first opening 333 or the lower side of the third opening 334. The second opening 335 generates the plasma through a hollow cathode effect that vibrates electrons in a cylindrical electrode. That is, the second opening 335 provides a large surface area to promote plasma ionization of the gas introduced into the second opening 335, thereby generating high-density plasma.

The second opening 335 may have a diameter D₃ of 10 mm to 14 mm. If the diameter D₃ of the second opening 335 is less than 10 mm, it is difficult to generate the hollow cathode effect, and thus, the high-density plasma may not be generated. In addition, when the diameter D₃ of the second openings 335 exceeds 14 mm, an interval between the second openings 335 may increase to deposit a uniform thin film. When the distance between the second openings 335 increases, the gas injected from each second opening 335 is concentrated at a predetermined position on the substrate S, which causes non-uniform deposition. However, if the distance between the second openings 335 is reduced, the gas injected from each second opening 335 may overlap the substrate S to deposit a more uniform thin film. To deposit the uniform thin film on the substrate S, the second openings 335 may need to be arranged at an interval of 12 mm to 20 mm, and when the diameter D₃ of the second opening 335 is controlled to 14 mm or less, the second opening 335 may be disposed at an interval of 12 mm to 20 mm to improve deposition uniformity.

The second opening 335 may have a length H₂ of 25 mm to 75 mm. That is, the second opening 335 may be provided to a length H₂ of 25 mm to 75 mm upward from the bottom surface of the second plate 330. If the length H₂ of the second opening 335 is less than 25 mm, a sufficient hollow cathode effect may not be generated. On the other hand, when the length H₂ of the second opening 335 exceeds 75 mm, ions generated in the second opening 335 may collide with the inner surface of the second plate 330 defining the second opening 335 to damage the hole due to sputtering. Thus, the second opening 335 may have a length H₂ of 25 mm to 75 mm.

As described above, the first opening 333 may have a length H₁ of 10 mm to 25 mm. In addition, the second opening 335 may have a length H₂ of 25 mm to 75 mm. Thus, the second plate 330 may be provided to a thickness of 35 mm to 100 mm. If the second plate 330 is provided to a thickness of less than 35 mm, the second plate 330 may sag due to its own weight, and if the second plate 330 is provided to a thickness exceeding 100 mm, the weight increases, and an excessive space is occupied in the chamber 10 to deteriorate structural efficiency, and thus, the second plate 330 may be provided to a thickness of 35 mm to 100 mm.

The length H₁ of the first opening 333 and the length H₂ of the second opening 335 may be respectively adjusted within a range of the set thickness of the second plate 330. That is, the length H₁ of the opening 333 and the length H₂ of the second opening 335 may be adjusted differently or identically.

For example, the length H₁ of the first opening 333 may be longer than the length H₂ of the second opening 335 to increase in density of the plasma within the range in which the second plate 330 has the set thickness. If the thickness of the second plate 330 is set to a thickness of 35 mm to 100 mm, and the length of the second opening 335 is set to a length H₂ of 25 mm, the first opening 333 may be set to the length H₁ exceeding 25 mm and less than or equal to 75 mm to increase in density of the plasma.

In addition, to lower the density of the plasma within the range in which the second plate 330 has the set thickness, the length H₁ of the first opening 333 may be less than the length H₂ of the second opening 335, i.e., the length H₂ of the second opening 335 may be greater than the length H₁ of the first opening 333. If the thickness of the second plate 330 is set to a thickness of 35 mm to 100 mm, and the length of the second opening 335 is set to a length H₂ of 25 mm, the first opening 333 may be set to the length H₁ of greater than 10 mm and less than 25 mm to decrease in density of the plasma.

The length H₁ of the first opening 333 and the length H₂ of the second opening 335 may be provided to be the same. As described above, the length H₁ of the first opening 333 and the length H₂ of the second opening 335 may be provided to be different from or the same as each other so that the plasma is adjusted to a desired density.

The power supply device 400 may be connected to the gas injection device 300 to supply power for generating plasma in the chamber 10 to the gas injection device 300. That is, the power supply device 400 may supply RF power for generating plasma in the chamber 10.

Here, the power supply device 400 may be connected to the second plate 330 to supply the RF power only to the second plate 330, and the first plate may be grounded. Here, the first plate and the second plate 330 may be insulated by a second sealing member 360 made of an insulating material. As described above, when the power supply device 400 supplies the RF power to the second plate 330, and the first plate is grounded, each of the first plate and the second plate 330 is provided as an electrode for generating capacitively coupled plasma (CCP). In addition, since the substrate support 22 may also be grounded, the capacitive coupled plasma may be generated between the second plate 330 and the substrate support 22.

Alternatively, the power supply device 400 may also supply power to the first plate and the second plate 330. In this case, the second sealing member 360 may be made of a conductive material so that the power supply device 400 supplies the RF power to the first plate or the second plate 330, or the power supply device 400 supplies the RF power to the first plate and the second plate 330. Here, the same RF power may be supplied to the first plate and the second plate 330. As described above, when the power supply device 400 supplies the same RF power to the first plate and the second plate 330, the plasma sheath region defined between the first plate and the second plate 330 is reduced compared to the case in which the first plate is grounded. Thus, the capacitive coupled plasma having a relatively high density may be generated between the plate and the grounded substrate support 22.

As described above, when using the apparatus for processing the substrate, the thin film may be deposited on the substrate S using a chemical vapor deposition (CVD) method or an atomic layer deposition (ALD) method. Here, the thin film deposited by the chemical vapor deposition method or the atomic layer deposition method may include at least one of an IZO thin film in which indium (In) is doped into zinc oxide (ZnO), a GZO thin film in which gallium (Ga) is doped into zinc oxide (ZnO), an IGZO thin film in which indium (In) and gallium (Ga) are doped into zinc oxide (ZnO), a thin film having a high dielectric constant (High-K), a silicon oxide (SiO₂) thin film, or a silicon nitride (SiN) thin film.

First, when the thin film is deposited on the substrate S by the chemical vapor deposition method, the source gas and the reaction gas may be simultaneously supplied onto the substrate S. Here, the first gas may include the source gas, and the second gas may include the reaction gas. However, it is not limited thereto, and the first gas may include a reaction gas, and the second gas may include a source gas, or at least one of the first gas or the second gas may include a mixed gas in which the source gas and the reaction gas are mixed. In addition, at least one of the first gas and the second gas may be a purge gas. Here, the power supply device 400 may supply the RF power to the gas injection device 300 to generate the plasma within the chamber 10, thereby improving deposition efficiency.

When the thin film is deposited on the substrate S by the atomic layer deposition method, the source gas and the reaction gas may be alternatively supplied onto the substrate S. Here, the first gas may include the source gas, and the second gas may include the reaction gas, or the first gas may include the reaction gas, and the second gas may include the source gas. In addition, at least one of the first gas and the second gas may be a purge gas. Here, a process of supplying the source gas, a process of supplying the purge gas, a process of supplying the reaction gas, and a process of supplying the purge gas may form one process cycle, and a process cycle may be repeated a plurality of times to deposit a thin film on the substrate S. Here, the power supply device 400 may supply the RF power to the gas injection device 300 to generate the plasma within the chamber 10. Thus, the process of supplying the reaction gas may be performed to improve deposition efficiency.

In accordance with an exemplary embodiment, the interval between the openings through which the process gas is injected may be minimized to improve the deposition uniformity. In addition, the high-density plasma may be generated using the hollow cathode effect, and thus, the high-quality thin film may be formed.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

1. A gas injection device comprising:
a first plate in which a first gas supply path and a second gas supply path are provided to be separated from each other and which has a first gas supply hole and a second gas supply hole, which are connected to the first gas supply path and the second gas supply path, respectively; and
a second plate spaced apart from the first plate and having a plurality of openings arranged alternately with the first gas supply hole and the second gas supply hole.

2. The gas injection device of claim 1, wherein the second plate is disposed to be spaced an interval of 1 mm to 3 mm from the first plate.

3. The gas injection device of claim 1, wherein the openings comprise:
a first opening defined at a side of the first plate; and
a second opening connected to the first opening and having a diameter greater than that of the first opening.

4. The gas injection device of claim 3, wherein the first opening has a diameter of 1 mm to 3 mm.

5. The gas injection device of claim 3, wherein the second opening has a diameter of 10 mm to 14 mm.

6. The gas injection device of claim 3, wherein the openings further comprise a third opening configured to connect the first opening to the second opening between the first opening and the second opening.

7. The gas injection device of claim 6, wherein the third opening has a shape of which a cross-section gradually increases toward the second opening.

8. The gas injection device of claim 3, wherein the second opening has a length of 25 mm to 75 mm.

9. The gas injection device of claim 1, wherein the second plate has a thickness of 35 mm to 100 mm.

10. The gas injection device of claim 1, wherein the openings are arranged at an interval of 12 mm to 20 mm.

11. The gas injection device of claim 3, wherein the first opening and the second opening have lengths different from each other.

12. The gas injection device of claim 11, wherein the first opening has a length greater than that of the second opening.

13. The gas injection device of claim 11, wherein the second opening has a length greater than that of the first opening.

14. An apparatus for processing a substrate, comprising:
a chamber;
a substrate support device installed in the chamber to support the substrate;
the gas injection device of claim 1, which is installed in the chamber to inject a gas to the substrate support device; and
a power supply device connected to the gas injection device to supply power to the gas injection device.

15. The apparatus for processing a substrate of claim 14, wherein the first plate and the second plate are electrically insulated from each other, and
the power supply device is connected to the second plate to supply power to the second plate.

16. The apparatus for processing a substrate of claim 14, wherein the power supply device is configured to supply power to the first plate and the second plate.

17. A method for depositing a thin film by using the gas injection device of any one of claim 1,
wherein a first gas is supplied through the first gas supply path, and a second gas is supplied through the second gas supply path to deposit the thin film on the substrate.

18. The method for depositing a thin film of claim 17, wherein at least one of the first gas or the second gas is supplied to deposit the thin film on the substrate in a chemical vapor deposition (CVD) manner or an atomic layer deposition (ALD) manner.

19. The method for depositing a thin film of claim 17, wherein the thin film comprises at least one of an IZO thin film in which indium (In) is doped into zinc oxide (ZnO), a GZO thin film in which gallium (Ga) is doped into zinc oxide (ZnO), an IGZO thin film in which indium (In) and gallium (Ga) are doped into zinc oxide (ZnO), a thin film having a high dielectric constant (High-K), a silicon oxide (SiO₂) thin film, or a silicon nitride (SiN) thin film.
